(19) United States
(12) Patent Application Publication
(10) Pub. No.: US 2025/0038672 A1
(43) Pub. Date: Jan. 30, 2025

(54) POWER CONVERSION DEVICE

(71) Applicant: TOSHIBA MITSUBISHI-ELECTRIC INDUSTRIAL SYSTEMS CORPORATION, Tokyo (JP)

(72) Inventors: Takumi HAGIWARA, Tokyo (JP); Yoshihiro TAWADA, Tokyo (JP)

(73) Assignee: TOSHIBA MITSUBISHI-ELECTRIC INDUSTRIAL SYSTEMS CORPORATION, Tokyo (JP)

(21) Appl. No.: 18/709,086

(22) PCT Filed: Oct. 31, 2022
(86) PCT No.: PCT/JP2022/040817

§ 371 Date: May 10, 2024

(51) Int. Cl. H02M 7/00; H05K 7/14; H05K 7/20

(52) U.S. Cl. CPC H02M 7/003; H05K 7/14325; H05K 7/20909

(57) ABSTRACT

A power conversion device includes: a first alternating current terminal, a second alternating current terminal, and a third alternating current terminal are arranged facing each other inside the housing, the first three-phase in one enclosure semiconductor unit is configured so that a signal distribution board of the power conversion device transmits a U-phase signal to the first alternating current terminal, a V-phase signal to the second alternating current terminal, and a W-phase signal to the third alternating current terminal, and the second three-phase in one enclosure semiconductor unit is configured so that the signal distribution board of the power conversion device replaces wiring so that the U-phase and W-phase are reversed, and transmits a W-phase signal to the first alternating current terminal, a V-phase signal to the second alternating current terminal, and a U-phase signal to the third alternating current terminal.

### TECHNICAL FIELD

The present invention relates to a power conversion device.

### BACKGROUND ART

Conventionally, in a power conversion device (power conditioning system (PCS)), one three-phase in one enclosure semiconductor unit would be arranged for one panel (housing) (see, for example, PTL 1).

In recent years, however, in power conversion devices for solar power generation and storage batteries, for example, the number of semiconductor devices such as insulated gate bipolar transistors (IGBTs) has been increasing as the capacity of inverters has expanded. For this reason, in recent years, in power conversion devices, multiple three-phase in one enclosure semiconductor units may be arranged in a single panel.

By the way, when multiple three-phase in one enclosure semiconductor units are arranged in a panel, it is preferable that the three-phase in one enclosure semiconductor units have the same structure from the viewpoint of, for example, ease of manufacture. For example, in conventional models in which multiple three-phase in one enclosure semiconductor units are arranged in a panel, multiple three-phase in one enclosure semiconductor units of the same structure are stacked in multiple layers in the panel like a server rack (see, for example, PTL 2).

### CITATION LIST

### Patent Literature

[PTL 1] JP 2017-204901 A
[PTL 2] WO 2019/207723

### SUMMARY OF THE INVENTION

### Problem to be Solved by the Invention

However, with the recent increase in the capacity of power conversion devices (inverters), the number of semiconductor elements used tends to increase further, and with the expansion of inverter capacity, the amount of heat generated per semiconductor element also tends to increase. As a result, the burden on the cooler also tends to increase, and the size of the cooler also tends to become larger. Therefore, the size of three-phase in one enclosure semiconductor units tends to be larger, and when considering cooling efficiency and exchangeability, it has become difficult to use the conventional layout of stacking multiple three-phase in one enclosure semiconductor units on a panel in a multi-stacked manner.

Although a three-phase in one enclosure semiconductor unit mainly consists of a cooler, semiconductor units, and a control board, the semiconductor units and control board need to be separated as much as possible from the outside air, where they are at risk of contamination. However, in a layout where multiple three-phase in one enclosure semiconductor units are stacked on a panel, the cooling flow paths become complicated and pressure losses increase when the semiconductor units and control board are separated from the outside air as much as possible. Also, if multiple three-phase in one enclosure semiconductor units are to be cooled evenly, the number of fans used will also increase.

An object of this disclosure is therefore to reduce the amount of conductors used, simplify and optimize conductor connections, while improving environmental resistance, guaranteeing cooling performance, simplifying cooling flow paths, and improving replaceability when multiple three-phase in one enclosure semiconductor units are arranged in the housing of a power conversion device.

### Means for Solving the Problem

A power conversion device according to one aspect of the present invention includes: a housing; a first three-phase in one enclosure semiconductor unit; and a second three-phase in one enclosure semiconductor unit, the first three-phase in one enclosure semiconductor unit and the second three-phase in one enclosure semiconductor unit being arranged in the housing and having the same structure, wherein the first three-phase in one enclosure semiconductor unit and the second three-phase in one enclosure semiconductor unit each include: a cooler, a semiconductor unit, a gate driver board, a first alternating current terminal, a second alternating current terminal, and a third alternating current terminal, the cooler is arranged in an outer portion of the housing, and the first alternating current terminal, the second alternating current terminal, and the third alternating current terminal are arranged facing each other inside the housing so that the semiconductor unit, the gate driver board, the first alternating current terminal, the second alternating current terminal, and the third alternating current terminal are arranged in an inner portion of the housing, the first three-phase in one enclosure semiconductor unit is configured so that a signal distribution board of the power conversion device transmits a U-phase signal to the first alternating current terminal, a V-phase signal to the second alternating current terminal, and a W-phase signal to the third alternating current terminal, and the second three-phase in one enclosure semiconductor unit is configured so that the signal distribution board of the power conversion device replaces wiring so that the U-phase and W-phase are reversed, and transmits a W-phase signal to the first alternating current terminal, a V-phase signal to the second alternating current terminal, and a U-phase signal to the third alternating current terminal.

### Advantageous Effects of the Invention

According to this disclosure, when multiple three-phase in one enclosure semiconductor units are arranged in the housing of a power conversion device, the amount of conductors used can be reduced and conductor connections can be simplified and optimized while improving environmental resistance, ensuring cooling performance, simplifying cooling flow paths, and improving replaceability.

### BRIEF DESCRIPTION OF THE DRAWINGS

FIG. 1 is a diagram showing an example of the configuration of a power conversion device according to a first embodiment.

FIG. 2 is a diagram showing an example of the configuration of the IGBT unit shown in FIG. 1.

FIG. 3 is a diagram showing an example of the layout structure of the components in the housing of the power conversion device shown in FIG. 1.

FIG. 4 is a side view showing an example of the division between the semiconductor cooling area and the electronic component area in the layout structure in the housing of the power conversion device shown in FIG. 3.

FIG. 5 is a rear view showing an example of the division between the semiconductor cooling area and the electronic component area in the layout structure in the housing of the power conversion device shown in FIG. 3.

FIG. 6 is a diagram showing an example of the control structure of the power conversion device shown in FIGS. 1 to 5.

FIG. 7 is a diagram showing an example of the control structure of the power conversion device shown in FIGS. 1 to 5.

FIG. 8 is a diagram showing an example of the layout structure of IGBT units in a power conversion device and the control configuration of a conventional signal distribution board.

FIG. 9 is a diagram showing an example of the layout structure of IGBT units and the control configuration of the signal distribution board in the power conversion device according to the first embodiment.

FIG. 10 is a diagram showing an example of the layout structure of the components and the division between the semiconductor cooling area and the electronic component area in the power conversion device according to a second embodiment.

FIG. 11 is a diagram showing an example of the layout structure of IGBT units in a power conversion device according to a third embodiment.

FIG. 12 is a diagram showing an example of the layout structure of IGBT units in a power conversion device according to a first comparative example.

FIG. 13 is a diagram showing an example of the layout structure of IGBT units in a power conversion device according to a second comparative example.

FIG. 14 is a diagram showing an example of the layout structure of IGBT units in a power conversion device according to a third comparative example.

### DESCRIPTION OF EMBODIMENTS

The following will describe an embodiment of the layout structure of three-phase in one enclosure semiconductor units, three-phase in one enclosure semiconductor units, and power conversion devices according to this disclosure with reference to the accompanying drawings.

### First Embodiment

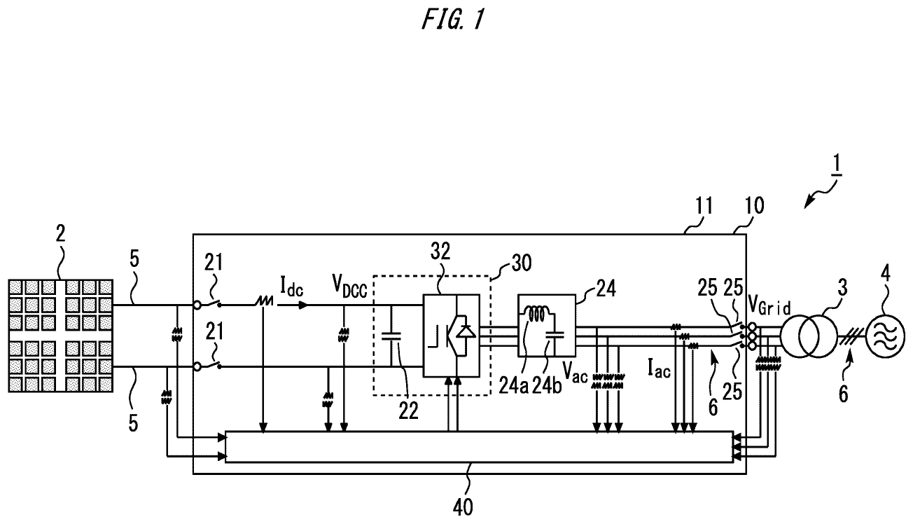

FIG. 1 is a diagram showing an example of the configuration of a power conversion device 10 according to a first embodiment. In this embodiment, a photovoltaic power generation system 1 in which the DC power source is a photovoltaic panel 2 will be described as an example of a power conversion system in which a power conversion device 10 is used. However, this is not necessarily the case, and the power conversion system using the power conversion device 10 of this embodiment may, for example, be one in which the DC power source is a storage battery or a combination of a solar battery and a storage battery.

As shown in FIG. 1, the photovoltaic power generation system 1 has a photovoltaic panel 2, a transformer 3, an AC power grid 4, a power conversion device 10, a direct current buses 5, and an alternating current circuit 6. The power conversion device 10 is connected to the photovoltaic panel 2 via the direct current bus 5 at the direct current terminal (input terminal) on the left side in FIG. 1, and is connected to the AC power grid 4 via the alternating current circuit 6 and transformer 3 at the alternating current terminal (output terminal) on the right side in FIG. 1. In the photovoltaic power generation system 1, the DC power generated in the photovoltaic panel 2 is converted to AC power via the power conversion device 10, and the AC power after conversion is supplied to the AC power grid 4 via the transformer 3.

The photovoltaic panel (solar battery panel) 2 is connected to the direct current terminals of the power conversion device 10 via the direct current buses 5. The photovoltaic panel 2 generates electricity by sunlight, and the generated DC power is supplied to the power conversion device 10 via the direct current buses 5. The photovoltaic panel 2 will hereinafter be also referred to as “PV panel 2” in this specification. The PV panel 2 is an example of a “DC power source,” and the “DC power source” may be, for example, an “energy storage system (ESS)”.

The transformer 3 is connected, at one terminal, to the alternating current terminal (output terminal) of the power conversion device 10 and, at the other terminal, to the AC power grid 4 via the alternating current circuit 6. The transformer 3 transforms the AC power output from the power conversion device 10 to a predetermined voltage and outputs it to the AC power grid 4.

The AC power grid (grid) 4 is an integrated system of generation, transformation, transmission, and distribution of AC power, connected to the transformer 3 and used to supply AC power transformed by the transformer 3 to the receiving facilities of consumers, and is connected to, for example, random load. The AC power grid 4 will hereinafter be also referred to as “grid 4” in this specification.

The direct current buses 5 are connected to the photovoltaic panel 2 at one terminal and to the direct current terminal (input terminal) of the three-phase in one enclosure semiconductor unit 30, which will be described below, at the other terminal. The direct current buses 5 supply DC power generated in the photovoltaic panel 2 to the three-phase in one enclosure semiconductor unit 30.

The alternating current circuit 6 is connected, at one terminal, to the alternating current terminal (output terminal) of the three-phase in one enclosure semiconductor unit 30 described below, and, at the other terminal, to the grid 4 via the transformer 3. The alternating current circuit 6 is, for example, a three-phase three-wire three-phase alternating current circuit that supplies three-phase AC power made by combining single-phase AC of three grids with current or voltage phases shifted from each other, using three wires, cables, and conductors. The alternating current circuit 6 supplies AC power converted by the three-phase in one enclosure semiconductor unit 30 to the grid 4 side.

The power conversion device (power conditioning system (PCS)) 10 is, for example, a power conversion device for photovoltaics (PV) (photovoltaics-power conditioning system (PV-PCS)). The power conversion device (PCS) 10 converts the DC power supplied from the photovoltaic panel 2 into AC power and outputs the AC power to the grid 4 side via the transformer 3. The power conversion device 10 will hereinafter be also referred to as “PCS 10” in this specification. Note that the PCS 10 may be a power conversion device for storage batteries (ESS) (energy storage system-power conditioning system (ESS-PCS)).

The PCS 10 includes a housing (panel) 11, and inside the housing 11, a direct current switch 21, three-phase in one enclosure semiconductor units 30, an alternating current filter 24, an AC switch 25, and a control device 40.

In the PCS 10, along the direct current buses 5 connected to the photovoltaic panel 2, the direct current switches 21 and the three-phase in one enclosure semiconductor units 30 are arranged in this order from the photovoltaic panel 2 side toward the three-phase in one enclosure semiconductor units 30. Various sensors are arranged between the photovoltaic panel 2 and the three-phase in one enclosure semiconductor units 30.

The PCS 10 has, in the alternating current circuit 6 connected to the grid 4 via the transformer 3, a three-phase in one enclosure semiconductor unit 30, an alternating current filter 24, and AC switches 25, in this order from the three-phase in one enclosure semiconductor unit 30 toward the transformer 3 (grid 4) side. Various sensors are arranged between the alternating current filter 24 and the transformer 3.

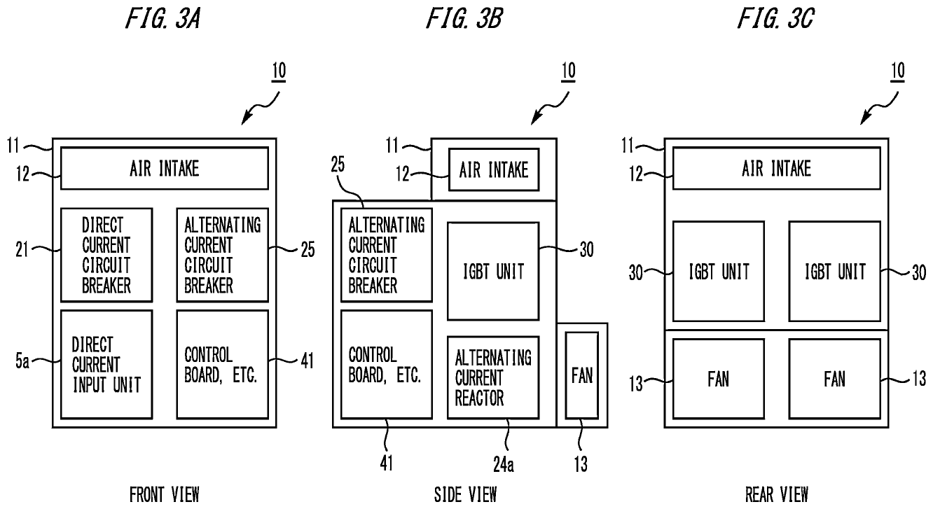

The specific layout structure inside the housing 11 in the PCS 10 will be described below (see FIGS. 3 to 5, for example).

The direct current switches (direct current circuit breakers) 21 are installed in series between the photovoltaic panel 2 and the three-phase in one enclosure semiconductor unit 30 in the direct current bus 5. The direct current switch 21 will hereinafter be also referred to as “direct current circuit breaker 21” or “DC switch 21” in this specification.

The alternating current filter 24 is also referred to as AC filter, and is configured, for example, as an LC filter circuit (filter circuit) consisting of an alternating current reactor 24a and an alternating current capacitor 24b connected in an L-shaped configuration. The alternating current filter 24 will hereinafter be also referred to as “AC filter 24,” alternating current reactor 24a as “AC reactor 24a,” and alternating current capacitor 24b as “AC capacitor 24b” in this specification.

Alternating current switches (alternating current circuit breakers) 25 are installed in series between the alternating current filter 24 and the transformer 3 in the alternating current circuit 6. The alternating current switches 25 will hereinafter be also referred to as “alternating current circuit breaker 25” or “AC switch 25” in this specification.

The three-phase in one enclosure semiconductor unit 30 includes direct current capacitors 22, a cooler 31, semiconductor units 32, and a gate driver board 33 which will be described below. The three-phase in one enclosure semiconductor unit 30 is connected to the DC switches 21 via the direct current buses 5 at one terminal serving a direct current terminal, and to the alternating current filter 24 via the alternating current circuit 6 at the other terminal serving as an alternating current terminal.

The three-phase in one enclosure semiconductor unit 30 includes, for example, multiple switching devices (semiconductor devices 32) such as insulated gate bipolar transistors (IGBTs). The three-phase in one enclosure semiconductor unit 30 acquires DC power supplied from the photovoltaic panel 2 from the direct current terminal, converts the acquired DC power into AC power according under control by the pulse width modulation signal (gate signal), and outputs it from the alternating current terminal to supply it to the alternating current circuit 6. The three-phase in one enclosure semiconductor unit 30 will hereinafter be also referred to as “IGBT unit 30” in this specification.

The direct current capacitors 22 are installed between the direct current switches 21 and the semiconductor units 32, and are charged by the DC power from the photovoltaic panel 2 to increase in voltage, and when the DC switches 21 are open, they are discharged through, for example, an unshown discharge circuit or discharge resistor to decrease in voltage. The direct current capacitors 22 will hereinafter be also referred to as “DC capacitors 22” in this specification.

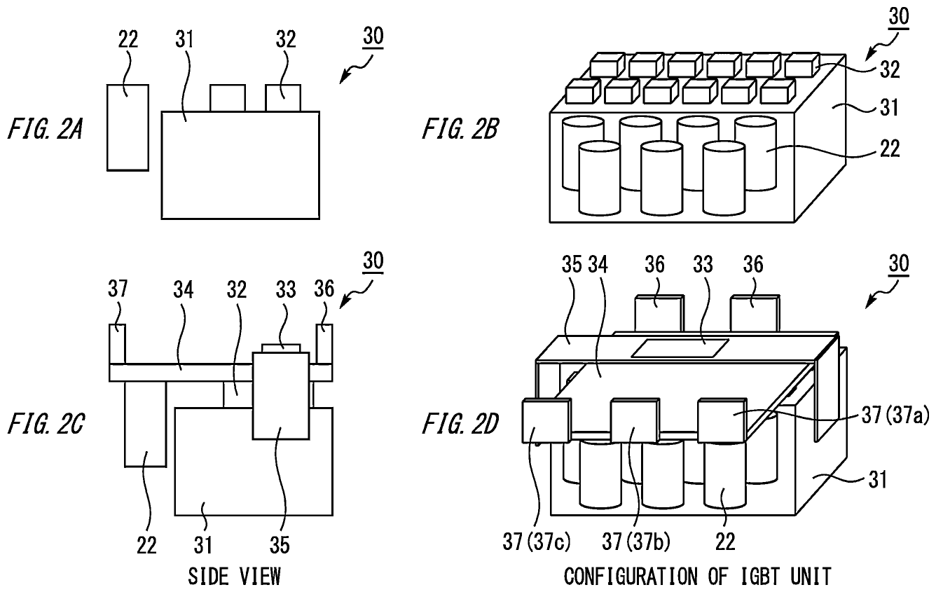

Other specific configurations and layout structures of the three-phase in one enclosure semiconductor unit (IGBT unit) 30 will be described below (see FIG. 2, for example).

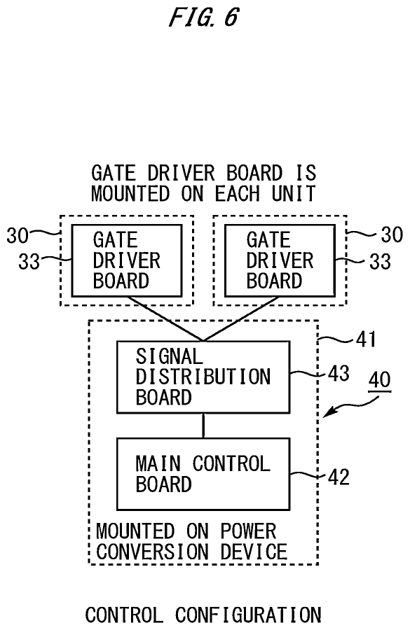

The control device 40 includes, for example, a control board 41 described below, and is electrically connected to each component of the PCS 10, including the IGBT unit 30, by wired or wireless means (see FIG. 6, for example), although some wiring and the like is omitted from the drawings.

The control device 40 includes, for example, an unshown processor such as a central processing unit (CPU) that operates by executing a program, and an unshown memory. The control device 40, for example, comprehensively controls the operation of the PCS 10 by operating the unshown processor by executing a predetermined program stored in the unshown memory. The control device 40 may control the operation of the PCS 10 according to instructions received from an unshown higher-level device or from an unshown operator via an unshown operation unit.

The control device 40, for example, generates a pulse width modulation (PWM) signal, which is a gate drive signal (gate signal) for the switching devices (semiconductor devices 32), from a three-phase output voltage command signal and a triangular wave carrier signal. The control device 40 controls the switching devices (semiconductor units 32) of the IGBT unit 30 using the generated gate signal to comprehensively control the operation of the IGBT unit 30. The pulse width modulation signal will hereinafter be also referred to as “PWM signal” and control based on the pulse width modulation signal will also be referred to as “PWM control” in this specification.

FIG. 2 is a diagram showing an example of the configuration of the IGBT unit 30 shown in FIG. 1. FIG. 2A is a side view showing an example of the configuration of a portion of the IGBT unit 30. FIG. 2B is a perspective view showing an example of the configuration of a portion of the IGBT unit 30. FIG. 2C is a side view showing an example of the overall configuration of the IGBT unit 30. FIG. 2D is a perspective view showing an example of the overall configuration of the IGBT unit 30.

As shown in FIGS. 2A and 2B, the IGBT unit 30 includes multiple DC capacitors 22, a cooler 31, and multiple semiconductor units 32.

In FIGS. 2A and 2B, the cooler 31 is arranged with its top surface adjoining multiple semiconductor units 32 and its front surface adjoining multiple DC capacitors 22. The cooler 31 includes, for example, multiple fins arranged in a flow of refrigerant and a fan circulating the refrigerant, and transfers heat dissipated from the multiple semiconductor devices 32 to the refrigerant, thereby cooling the adjoining multiple semiconductor devices 32 and other components in the IGBT unit 30.

The multiple semiconductor units (semiconductor units) 32 are arranged to adjoin one surface of the cooler 31. The multiple semiconductor units 32 are multiple switching devices, such as IGBTs, which convert DC power to AC power according to control by the gate signal from the control device 40 (control board 41) via a gate driver board 33 described below.

As shown in FIGS. 2C and 2D, the IGBT unit 30 also has a gate driver board 33, a main circuit conductor 34, a support member 35, direct current terminals 36, and alternating current terminals 37.

Referring to FIGS. 2C and 2D, the gate driver board 33 is arranged over the support member 35 which is located on the top surface of the multiple semiconductor units 32. The gate driver board 33 controls the semiconductor units 32 by transmitting the gate signal output from the control device 40 (control board 41) to the gates of the multiple semiconductor units (semiconductor devices) 32.

Referring to FIGS. 2C and 2D, the main circuit conductor 34 (laminated bus bar) is arranged over the DC capacitors 22 and semiconductor units 32, with direct current terminals 36 on the cooler 31 side and alternating current terminals 37 on the DC capacitors 22 side. The main circuit conductor 34 is, for example, a laminated bus bar in which multiple conductive layers and insulating layers are stacked in a predetermined layout from the direct current terminals 36 to the alternating current terminals 37.

Referring to FIGS. 2C and 2D, the support member 35 is supported by the cooler 31 and arranged above the main circuit conductor 34, and the gate driver board 33 is arranged over the support member 35.

Referring to FIGS. 2C and 2D, the direct current terminals 36 are installed on the cooler 31 side of the main circuit conductor 34 and is connected to the direct current buses 5 outside the IGBT unit 30 (see FIG. 1, for example).

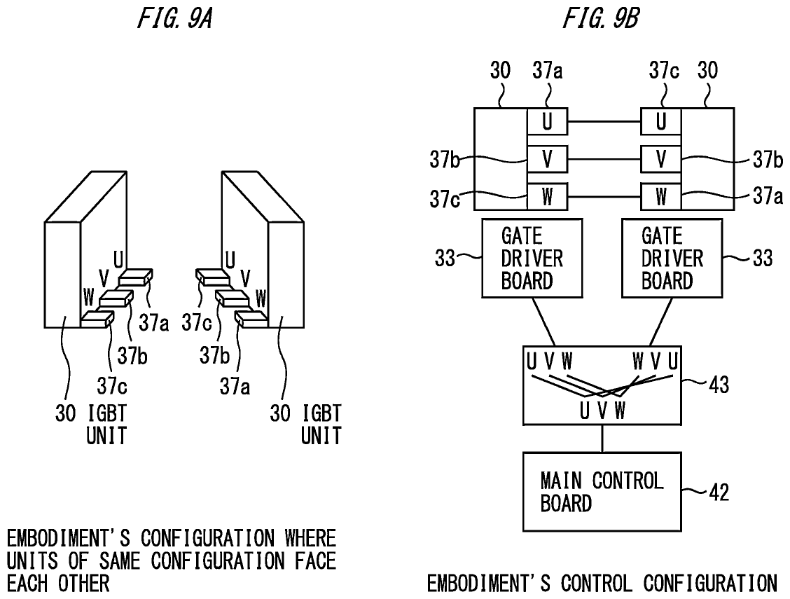

Referring to FIGS. 2C and 2D, the alternating current terminals 37 are installed on the DC capacitors 22 side of the main circuit conductor 34 and are connected to the alternating current circuit 6 outside the IGBT unit 30 (see FIG. 1, for example). The alternating current terminals 37 each have three terminals: an alternating current terminal 37a, an alternating current terminal 37b, and an alternating current terminal 37c, as described below (see FIG. 9, for example). The alternating current terminal 37a is an example of a “first alternating current terminal,” the alternating current terminal 37b is an example of a “second alternating current terminal,” and the alternating current terminal 37c is an example of a “third alternating current terminal.”

FIG. 3 is a diagram showing an example of the layout structure of the components in the housing 11 of the power conversion device 10 shown in FIG. 1. FIG. 3A is a front view showing an example of the layout structure of the components in the housing 11 of the power conversion device 10 shown in FIG. 1. FIG. 3B is a side view showing an example of the layout structure of the components in the housing 11 of the power conversion device 10 shown in FIG. 1. FIG. 3C is a rear view showing an example of the layout structure of the components in the housing 11 of the power conversion device 10 shown in FIG. 1. Note that FIG. 3B is the right side view of FIG. 3A.

As shown in FIG. 3A, in front view, the power conversion device 10 has, inside the housing 11, the air intake 12 in the upper section, direct current circuit breaker 21 in the middle left side, alternating current circuit breaker 25 in the middle right side, direct current input unit 5a in the lower left side, control board 41 in the lower right side, and the like.

As shown in FIG. 3B, in side view, the power conversion device 10 has the alternating current circuit breaker 25 in the middle front side, control board 41 in the lower front side, and the like. In addition, in side view, the power conversion device 10 has the air intake 12 in the upper middle section, IGBT unit 30 in the middle section, and alternating current reactor 24a in the lower middle section. In side view, the power conversion device 10 also has a fan 13 in the lower rear side.

As shown in FIG. 3C, in rear view, the power conversion device 10 has the air intake 12 in the upper section, IGBT units 30 on both the left and right sides of the middle section, and fans 13 on both the left and right sides of the lower section. The two IGBT units 30 arranged on both the left and right sides are of the same structure for ease of manufacture and other reasons.

In FIGS. 3A to C, the control board 41 and the like implements a main control board 42 and a signal distribution board 43 which will be described below (see FIG. 6, for example).

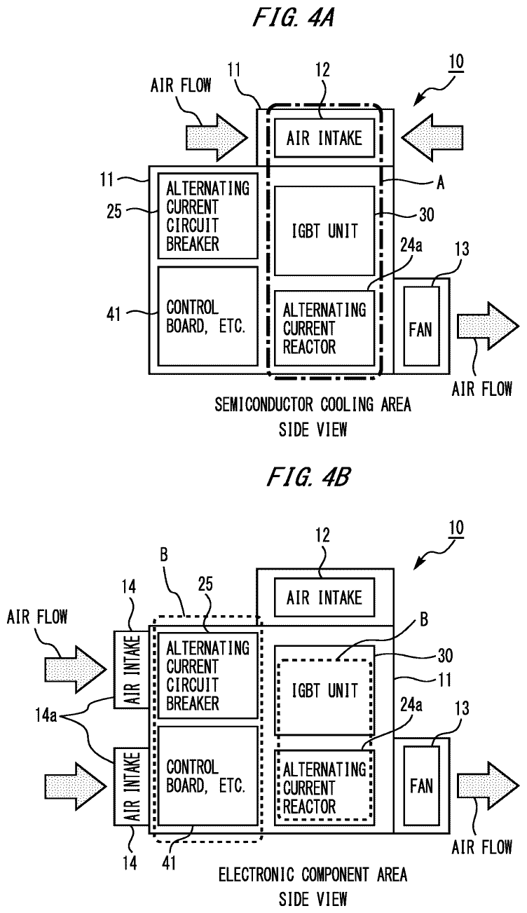

FIG. 4 is a side view showing an example of the division between the semiconductor cooling area A and the electronic component area B in the layout structure in the housing 11 of the power conversion device 10 shown in FIG. 3. FIG. 4A is a side view showing an example of the semiconductor cooling area A in the layout structure inside the housing 11 of the power conversion device 10 shown in FIG. 3. FIG. 4B is a side view showing an example of the electronic component area B in the layout structure inside the housing 11 of the power conversion device 10 shown in FIG. 3. Note that FIGS. 4A and 4B are right side views of FIG. 3A similarly to FIG. 3B.

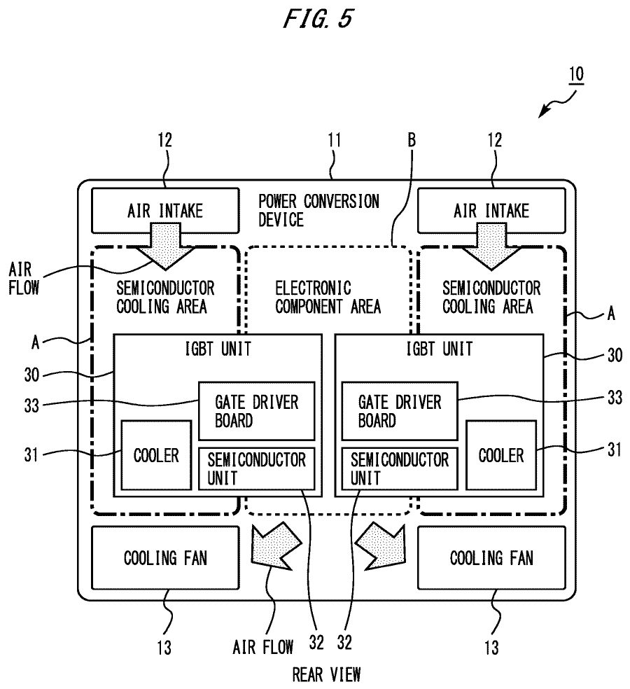

In FIG. 4A, the semiconductor cooling area A is, for example, the outer area to the left and right of the IGBT unit 30 and the alternating current reactor 24a in front and rear views, where outside air is taken in through the air intake 12 and exhausted through the fan 13 (see FIG. 5, for example).

The air intake 12 is, for example, a punched metal sheet and actively takes in outside air to cool the semiconductor units 32 (for the cooler 31 that cools the semiconductor units 32). The semiconductor cooling area A is an area where improvement of cooling performance is more important than suppression of the risk of contamination by outside air. In the semiconductor cooling area A, of the IGBT units 30, the cooler 31 where the improvement of cooling performance is more important than the risk of contamination by outside air (see FIG. 5, for example), is arranged in the semiconductor cooling area A. Note that the air intake 12 is an example of “first air intake”.

The fan (cooling fan) 13 is installed on the rear side of the lower part of the housing 11. Referring to FIG. 4A, as indicated by the arrows showing the flow of air, outside air taken in from the air intake 12 and passing through the semiconductor cooling area A is exhausted from the fan (cooling fan) 13.

In FIG. 4B, the electronic component area B is, for example, the inner area in front and rear views (see FIG. 5, for example), and air is taken in from the air intake 14 dedicated to the electronic component area B installed on the front side of the housing 11. The electronic component area B can take in cleaner air than the semiconductor cooling area A, although the air volume in the electronic component area B is lower than that in the semiconductor cooling area A.

The air intake 14, for example, has an air filter 14a and takes in clean air through the air filter 14a. The electronic component area B is an area where the control of the risk of contamination by outside air is more important than the improvement of cooling performance. In the electronic component area B, of the 30 IGBT units, the semiconductor units 32 and gate driver board 33, which need to be separated from the outside air that can put them at the risk of contamination, are arranged facing each other (see FIG. 5, for example). Note that the air intake 14 is an example of “second air intake.”

Note that, as shown in FIG. 2, the IGBT units 30 are pre-designed so that the areas are physically separated by, for example, a bulkhead or metal sheet of the cooler 31, thereby preventing the semiconductor units 32 and gate driver board 33 are not exposed to outside air. The semiconductor cooling area A and the electronic component area B have different air intake units, the air intake 12 and air intake 14, and are designed to be structurally separated inside the housing 11.

Referring to FIG. 4B, as indicated by the arrows that show the flow of air, clean air taken in from the air intake 14 passes through the electronic component area B and is exhausted from the fan (cooling fan) 13. In other words, in this embodiment, the exhaust section is shared between the semiconductor cooling area A and electronic component area B, and the outside air flowing through the semiconductor cooling area A and the clean air flowing through the electronic component area B merge and are exhausted from the same fan 13. However, this is not necessarily the case, and the outside air that flows through the semiconductor cooling area A and the clean air that flows through the electronic component area B may be exhausted separately without merging.

FIG. 5 is a rear view showing an example of the division between the semiconductor cooling area A and the electronic component area B in the layout structure in the housing 11 of the power conversion device 10 shown in FIG. 3.

In FIG. 5, as explained above with reference to FIG. 3C, in rear view, the housing (panel) 11 of the power conversion device 10 has the air intake 12 in the upper section, IGBT units 30 on both the left and right sides of the middle section, and fans 13 on both the left and right sides of the lower section. As shown in FIG. 5, the left and right outer portions are the semiconductor cooling area A and the inner portion is the electronic component area B. As explained above with reference to FIG. 3C, the two IGBT units 30 arranged on both the left and right sides are of the same structure for ease of manufacture and other reasons.

As explained above with reference to FIG. 4A, the semiconductor cooling area A are, for example, an area where outside air is actively taken in through the air intake 12, and of the IGBT units 30, the coolers 31, which have little need to be separated from the outside air that can put it at the risk of contamination, and the alternating current reactor 24a are arranged. Hence, the coolers 31 are arranged on both the left and right outer sides of the IGBT units 30.

As explained above with reference to FIG. 4B, the electronic component area B, on the other hand, takes in clean air from the air intake 14 dedicated to the electronic component area B which has an air filter 14a on the front side of the housing 11. The electronic component area B is an area where cleaner air is taken in than in the semiconductor cooling area A, although the air volume is lower than in the semiconductor cooling area A. In the electronic component area B, of the IGBT units 30, the semiconductor units 32 and gate driver board 33 which need to be separated from the outside air that can put them at the risk of contamination are arranged. Hence, the semiconductor units 32 and gate driver board 33 are arranged facing each other inside the IGBT units 30.

Referring to FIG. 5, as indicated by the arrows that show the flow of air, clean air taken in from the air intakes 12 passes through the semiconductor cooling area A and is exhausted from the fans (cooling fans) 13. Also, although not shown in FIG. 5, clean air taken in through the air intakes 14 merges with the outside air through the electronic component area B and is exhausted from the fans (cooling fans) 13 (see FIG. 4B, for example).

According to the aforementioned configuration, of the IGBT units 30 and alternating current reactor 24a in the power conversion device 10 (housing 11), the outer portions can be partitioned as the semiconductor cooling area A and the inner portion as the electronic component area B. This allows the semiconductor units 32 and gate driver board 33, which need to be separated from the outside air that can put them at the risk of contamination, to be arranged facing each other in the electronic component area B, thereby improving environmental resistance. The aforementioned configuration also simplifies the cooling flow path for the IGBT units 30, enabling a layout with low pressure loss.

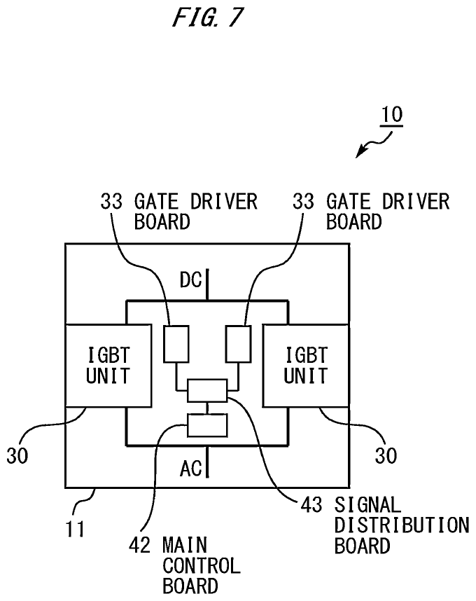

FIGS. 6 and 7 are diagrams showing an example of the control configuration of the power conversion device 10 shown in FIGS. 1 to 5.

As shown in FIGS. 6 and 7, inside the housing 11 of the power conversion device 10, the control board 41 in the control device 40 has a main control board 42 and a signal distribution board 43. Each of the IGBT units 30 arranged on the left and right in the front and rear views of the housing 11 of the power conversion device 10 has a gate driver board 33.

The main control board 42 is a board that actually performs the control and generates and outputs the gate signal that turns on and off the gates of the semiconductor units (semiconductor devices) 32 of the IGBT units 30.

The signal distribution board 43 is a board that replaces (switches) wiring to transmit signals output from the main control board 42 to each gate driver board 33. The signal distribution board 43 splits (divides) the signal output from the main control board 42 and outputs it to each gate driver board 33.

The gate driver board 33 is a board that controls the corresponding semiconductor unit 32 by transmitting electrical signals output from the control board 41 to the gates of the multiple semiconductor units (semiconductor devices) 32 insulated with, for example, a photocoupler (see FIG. 2, for example).

The IGBT units 30 convert the DC power supplied from the direct current terminals 36 into AC power and outputs it from the alternating current terminals 37 according to the gate signal output from the main control board 42 and distributed to each gate driver board 33 by the signal distribution board 43. As shown in FIG. 7, the DC power is split into two and supplied to the two IGBT units 30, and the AC power converted and output by the two IGBT units 30 respectively is merged after being output from the two IGBT units 30.

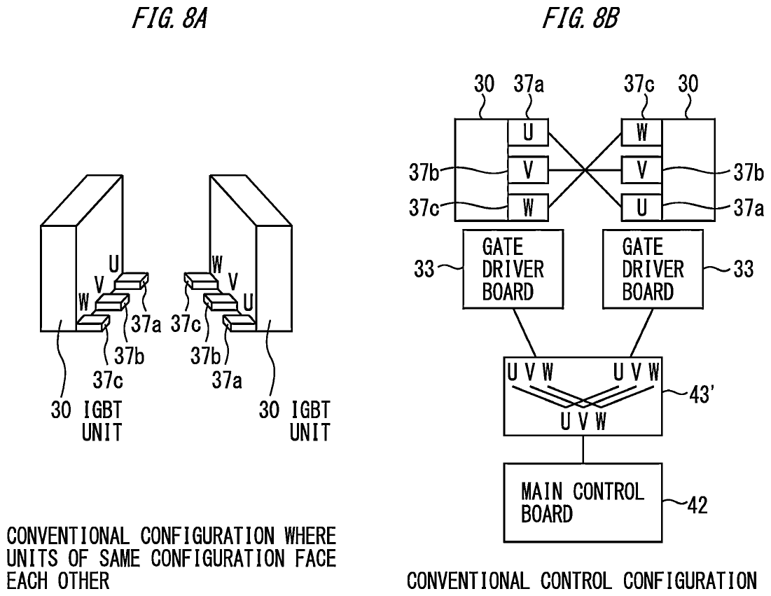

FIG. 8 is a diagram showing an example of the layout structure of the IGBT units 30 in the power conversion device 10 and the control configuration of a conventional signal distribution board 43′. FIG. 8A is a diagram showing an example of the layout structure of the IGBT units 30 in the power conversion device 10. FIG. 8B is a diagram showing an example of the control configuration of the conventional signal distribution board 43′ in the power conversion device 10.

As explained above with reference to FIGS. 1 to 5, in this embodiment, when two IGBT units 30 are arranged in the housing 11, the semiconductor units 32 and the gate driver boards 33 are arranged facing each other in the electronic component area B (see FIG. 5, for example). As mentioned above, the two IGBT units 30 on the left and right sides have the same structure for ease of manufacture and other reasons. Therefore, as explained above in FIGS. 6 and 7, U-, V-, and W-phase ones have to be connected to each other in order to merge the AC power output from the two IGBT units 30 into one.

However, as shown in FIG. 8A, if two IGBT units 30 of the same structure are simply arranged facing each other, the alternating current terminals 37a of phase U and alternating current terminals 37c of phase W are arranged facing each other. Therefore, when those of phase U, those of phase V, or those of phase W are connected to each other, the alternating current terminals 37a and 37c have to be connected to each other, and the connections between phases U, V, and W will intersect (cross).

This is because, as shown in the middle section of FIG. 8B, conventionally, when the signal distribution board 43′ distributes a signal to the two IGBT units 30, it would send the same signal to the alternating current terminals 37a to 37c of each of the two IGBT units 30. In other words, via the gate driver boards 33, the signal distribution board 43′ sends a U-phase signal to the alternating current terminal 37a of each of the two IGBT units 30, a V-phase signal to the alternating current terminal 37b of each unit, and a U-phase signal to the alternating current terminal 37a of each unit.

Therefore, as shown in the top section of FIG. 8B, when those of phase U, V, or W are connected to each other, the alternating current terminals 37a and 37c have to be connected to each other, resulting in the problem of cross connection between U, V, and W phases. In case of cross connection between the U, V, and W phases, the connection distance for each conductor will be longer, and a more amount of conductors will be used than if they were connected with the shortest distance.

FIG. 9 is a diagram showing an example of the layout structure of the IGBT units 30 and the control configuration of the signal distribution board 43 in the power conversion device 10 according to the first embodiment. FIG. 9A is a diagram showing an example of the layout structure of the IGBT units 30 in the power conversion device 10 according to the first embodiment. FIG. 9B is a diagram showing an example of the control configuration of the signal distribution board 43 in the power conversion device 10 according to the first embodiment.

As shown in FIG. 9A, in this embodiment, one IGBT unit 30 has alternating current terminals 37a, 37b, and 37c of U, V, and W phases, respectively, while the other IGBT unit 30 has alternating current terminals 37a, 37b, and 37c of phases W, V, and U, respectively. Therefore, as shown in FIG. 9A, the alternating current terminal 37a of phase U and the alternating current terminal 37c of phase U are arranged facing each other, even when the two IGBT units 30 that have the same structure in terms of manufacturability and the like are arranged facing each other. Similarly, the alternating current terminal 37b of phase V and the alternating current terminal 37b of phase V are arranged facing each other, and the alternating current terminal 37c of phase W and the alternating current terminal 37a of phase W are arranged facing each other. Consequently, when those of phase U, V, or W are connected to each other, the connections do not cross (intersect) and those of phase U, V, or W are connected to each other at the shortest distance.

In other words, as shown in the middle section of FIG. 9B, when distributing signals to the two IGBT units 30, the signal distribution board 43 according to this embodiment sends U-, V-, and W-phase signals to the alternating current terminals 37a, 37b, and 37c of one of the IGBT units 30, respectively. On the other hand, the signal distribution board 43 sends signals of phases W, V, and U to the alternating current terminals 37a, 37b, and 37c of the other IGBT unit 30, respectively, switching the wiring so that signals of phases U and W are reversed.

Accordingly, as shown in the upper section of FIG. 9B, when those of phase U are connected to each other, an alternating current terminal 37a of phase U and an alternating current terminal 37c of phase U that is arranged facing that alternating current terminal 37a of phase U are connected at the shortest distance facing each other without crossing. Similarly, when those of phase V are connected to each other, an alternating current terminal 37b of phase V and an alternating current terminal 37b of phase V that is arranged facing that alternating current terminal 37b of phase V are connected at the shortest distance facing each other without crossing. Similarly, when those of phase W are connected to each other, an alternating current terminal 37c of phase W and an alternating current terminal 37a of phase W that is arranged facing that alternating current terminal 37c of phase W are connected at the shortest distance facing each other without crossing.

Therefore, according to this embodiment, the connections between U, V, and W phases do not cross, nor do the connection distances between conductors become longer. Besides, since those of phases U, V, are W are connected at the shortest distance, the amount of conductors used can be reduced, and the conductor connections can be simplified and optimized. Note that one of the IGBT units 30 is an example of “first three-phase in one enclosure semiconductor unit” and the other IGBT unit 30 is an example of “second three-phase in one enclosure semiconductor unit.”

### Effects of First Embodiment

According to the first embodiment shown in FIGS. 1 to 7 and 9, the outer portions of the power conversion device 10 (housing 11) are partitioned as the semiconductor cooling area A and the inner portion as the electronic component area B, thereby arranging the IGBT units 30 facing each other. According to this embodiment, this allows for a simpler cooling flow path and a layout with less pressure loss, even when two (multiple) IGBT units 30 are arranged in the housing 11.

According to the first embodiment shown in FIGS. 1 to 7 and 9, the cooler 31 of the IGBT units 30 is arranged in the semiconductor cooling area A where outside air is actively taken in and where improving cooling performance is more important than controlling the risk of contamination by outside air. This ensures, according to this embodiment, the cooling of the semiconductor units 32 even when two (multiple) IGBT units 30 are arranged in the housing 11.

According to the first embodiment shown in FIGS. 1 to 7 and 9, of the two (multiple) IGBT units 30, the semiconductor units 32 and the gate driver boards 33, which need to be separated from the outside air that can put them at the risk of contamination, are arranged facing each other in the electronic component area B. Accordingly, the semiconductor units 32 and gate driver boards 33, which need to be separated from the outside air that can put them at the risk of contamination, are arranged in the electronic component area B, where clean air is taken in, although the air volume is lower than in the semiconductor cooling area A. Therefore, according to this embodiment, environmental resistance can be improved.

According to the first embodiment shown in FIGS. 1 to 7 and 9, for distributing signals to the two (multiple) IGBT units 30, the signal distribution board 43 sends U-, V-, and W-phase signals to the alternating current terminals 37a, 37b, and 37c of one of the IGBT units 30, respectively. On the other hand, the signal distribution board 43 sends signals of phases W, V, and U to the alternating current terminals 37a, 37b, and 37c of the other IGBT unit 30, respectively, switching the wiring so that signals of phases U and W are reversed. As a result, according to this embodiment, even when two (multiple) IGBT units 30 are arranged in the housing 11, the connections of U, V, and W phases do not cross (intersect) and become complicated, and the connection distances between conductors are prevented from becoming longer. Therefore, according to this embodiment, those of phases U, V, are W are arranged facing each other and the conductors are connected at the shortest distance, so that the amount of conductors used can be reduced and the conductor connections can be simplified and optimized.

In addition, according to the first embodiment shown in FIGS. 1 to 7 and 9, the control configuration of the signal distribution board 43 is changed so that one of the IGBT units 30 facing the other is not rewired, but only the other IGBT unit 30 is rewired so that the signals of phases U and W are reversed. Thus, according to this embodiment, even if two (multiple) IGBT units 30 are arranged in the housing 11, the two IGBT units 30 can be of the same structure, thereby improving manufacturability and replaceability.

### Second Embodiment

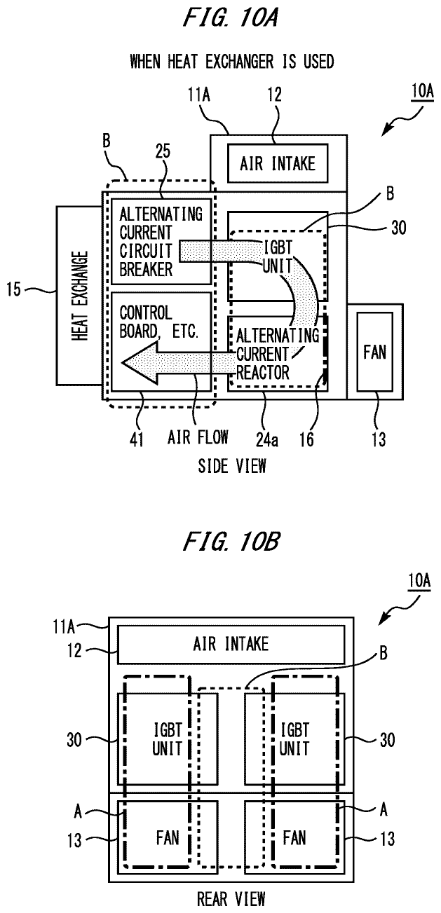

FIG. 10 is a diagram showing an example of the layout structure of the components and the division between the semiconductor cooling area A and the electronic component area B in the power conversion device 10A according to the second embodiment. FIG. 10A is a side view showing an example of the layout structure of the components and the division between the semiconductor cooling area A and the electronic component area B in the power conversion device 10A according to the second embodiment. FIG. 10B is a rear view showing an example of the layout structure of the components and the division between the semiconductor cooling area A and the electronic component area B in the power conversion device 10A according to the second embodiment. In FIG. 10, a configuration that is the same or substantially the same as any of those in the first embodiment shown in FIGS. 1 to 7 and 9 is denoted by the same reference numeral as the corresponding one, and its detailed description will be omitted or simplified.

As described above, in the power conversion device 10 according to the first embodiment shown in FIGS. 1 to 7 and 9, an air intake 14 dedicated to the electronic component area B with an air filter 14a is installed on the front side of the housing 11 (see FIG. 4, for example). In the power conversion device 10 according to the first embodiment, clean air taken in from the air intake 14 through the air filter 14a passes through the electronic component area B, merges with the outside air in the semiconductor cooling area A, is exhausted from the shared fan 13.

On the other hand, as shown in FIG. 10, in the power conversion device 10A according to the second embodiment, a heat exchanger 15 is installed on the front side of the housing 11A instead of the air filter 14a, and a bulkhead 16, for example, is arranged between the electronic component area B and the fan 13.

The heat exchanger 15 absorbs and cools the heat of clean air (internal air) heated by the dissipation of, for example, the semiconductor units 32 in the electronic component area B.

The bulkhead 16 is, for example, a metal sheet, and blocks the exhaust portion on the electronic component area B side (between the electronic component area B and the fan 13) inside the housing (panel) 11A. One used to block the exhaust portion on the electronic component area B side is not limited to the bulkhead 16. For example, the power conversion device 10A (housing 11) may have a structure in which the exhaust portion on the electronic component area B side is blocked from the beginning.

Referring to FIG. 10A, as indicated by the arrow showing an air flow, clean air (internal air) heated in the electronic component area B is cooled by the heat exchanger 15. Because the exhaust portion on the electronic component area B side in the housing (panel) 11A is blocked by the bulkhead 16, the internal air in the electronic component area B does not merge with the external air in the semiconductor cooling area A, but is separated from the exhaust of the external air from the fan 13. As a result, in the power conversion device 10A according to the second embodiment, the internal air is completely separated from the external air, and only the cooling air of the internal air, which is cooled by heat absorption by the heat exchanger 15, circulates and flows in the electronic component area B. Then, only the outside air is exhausted from the fan 13.

### Effects of Second Embodiment

The second embodiment shown in FIG. 10 has the same effects as the first embodiment shown in FIGS. 1 to 7 and 9.

In addition, according to the second embodiment shown in FIG. 10, the inside of the electronic component area B can be kept cleaner and more environmentally resistant than in the first embodiment, because the inside and outside air can be completely separated.

In addition, according to the second embodiment shown in FIG. 10, since the inside and outside air can be completely separated, outside air can be taken into the semiconductor cooling area A more actively than in the first embodiment, without taking into account the risk of contamination. As a result, according to this embodiment, the cooling performance can be improved and cooling effect can be secured more than in the first embodiment.

### Third Embodiment

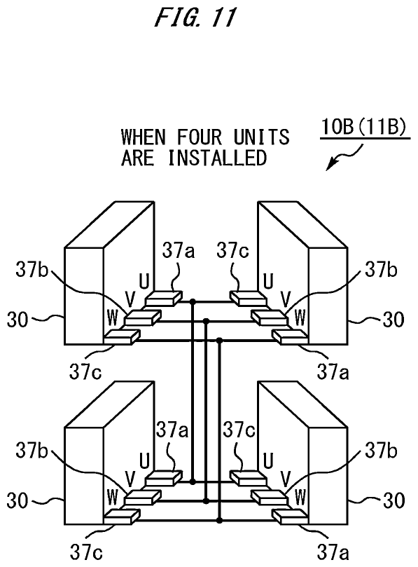

FIG. 11 is a diagram showing an example of the layout structure of IGBT units 30 in a power conversion device 10B according to a third embodiment. In FIG. 11, a configuration that is the same or substantially the same as any of those in the first embodiment shown in FIGS. 1 to 7 and 9 is denoted by the same reference numeral as the corresponding one, and its detailed description will be omitted or simplified.

As shown in FIG. 11, in the power conversion device 10B according to the third embodiment, four IGBT units 30 are arranged inside the housing 11B. In addition, as in the first embodiment shown in FIGS. 1 to 7 and 9, the IGBT units 30 are arranged facing each other, and each pair of two IGBT units 30 facing each other are arranged above and below. As in the first embodiment, those of U, V, and W phases of each pair of IGBT units 30 arranged facing each other are connected to each other at the shortest distance in a direction in which they face each other, and the upper and lower ones of U, V, and W phases are connected to each other in the vertical direction.

This means that, in the third embodiment also, the control configuration of the signal distribution board 43 is changed, as the signal distribution board 43 has the same configuration as in the first embodiment. In other words, one of the IGBT units 30 arranged facing each other is not rewired by the signal distribution board 43, while the other IGBT unit 30 is rewired by the signal distribution board 43 so that the signals of phases U and W are reversed. Accordingly, in the third embodiment, those of U, V, and W phases of each pair of IGBT units 30 arranged facing each other can be connected to each other at the shortest distance in a direction in which they face each other, and the upper and lower ones of U, V, and W phases can be connected to each other in the vertical direction.

The number of IGBT units 30 in the third embodiment is not limited to four, but may be any even number of units, such as six, for example. In this case, pairs of IGBT units 30 each facing each other are aligned two by two in the vertical direction (up-and-down direction). In addition, the conductors of U, V, and W phases of the multiple IGBT units 30 aligned in the vertical direction are connected horizontally facing each other and also connected in the vertical direction (up-and-down direction).

### Effects of Third Embodiment

The third embodiment shown in FIG. 11 has the same effects as the first embodiment shown in FIGS. 1 to 7 and 9, even when an even number of four or more IGBT units 30 are arranged in the housing 11B.

In the third embodiment shown in FIG. 11, as in the case where two IGBT units 30 are arranged, inverting the phases U and W for one of the IGBT units 30 facilitates the conductor connection for each phase between ones facing each other, as well as the conductor connection for each phase between upper and lower ones.

### First Comparative Example

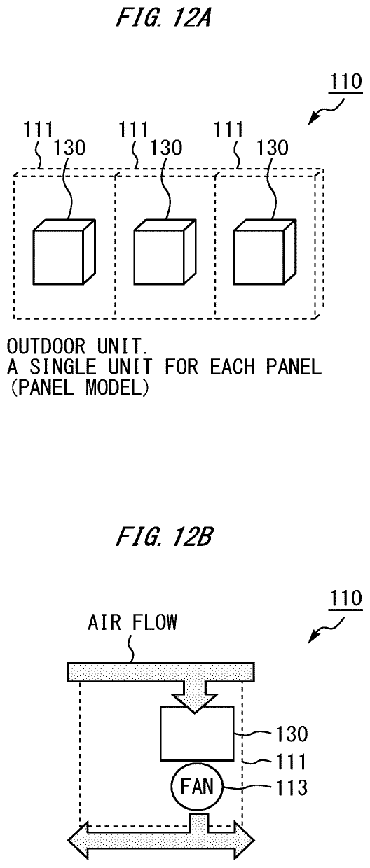

FIG. 12 is a diagram showing an example of the layout structure of IGBT units 130 in a power conversion device 110 according to a first comparative example. FIG. 12A is a perspective view showing an example of the layout structure of IGBT units 130 in the power conversion device 110 according to the first comparative example. FIG. 12B is a side view showing an example of the layout structure of IGBT units 130 in the power conversion device 110 according to the first comparative example.

The power conversion device 110 according to the first comparative example is, for example, an outdoor unit of the panel model. As shown in FIGS. 12A and 12B, a single IGBT unit 130 is installed for each panel (housing) 111, and a fan 113 is arranged under the IGBT units 130. In recent years, in power conversion devices 110 for solar power generation and storage batteries, for example, the number of semiconductor devices such as IGBTs has been increasing as the capacity of inverters has expanded, and it has been required to arrange multiple IGBT units 130 for a single panel 111. However, in the structure of the first comparative example shown in FIG. 12, multiple IGBT units 130 cannot be arranged for a single panel 111.

On the other hand, according to the first to third embodiments shown in FIGS. 1 to 7 and 9 to 11, multiple IGBT units 30 can be arranged. In addition, according to the first to third embodiments shown in FIGS. 1 to 7 and FIGS. 9 to 11, compared with the first comparative example, the amount of conductors used can be reduced and conductor connections can be simplified and optimized while improving environmental resistance, ensuring cooling performance, simplifying cooling flow paths, and improving replaceability.

### Second Comparison Example

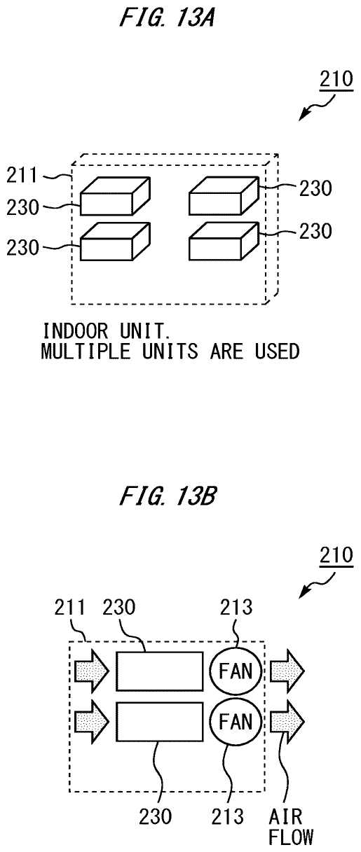

FIG. 13 shows an example of the layout structure of IGBT units 230 in a power conversion device 210 according to the second comparative example. FIG. 13A is a perspective view showing an example of the layout structure of the IGBT units 230 in the power conversion device 210 according to the second comparative example. FIG. 13B is a side view showing an example of the layout structure of the IGBT units 230 in the power conversion device 210 according to the second comparative example.

As shown in FIGS. 13A and 13B, the power conversion device 210 is, for example, an indoor device, and includes, for a single panel (housing) 211, multiple IGBT units 230 arranged in multiple layers in the panel 211 like a server rack. In this case, in a single panel 211, multiple fans 213 need to be arranged horizontally with the IGBT units 230, according to the number of IGBT units 230. This is because, for example, if the fans 213 are arranged at the bottom as in the first comparative example shown in FIG. 12, the IGBT units 230 above and the IGBT units 230 below, which are stacked in multiple layers like a server rack, cannot be cooled evenly. For this reason, in the structure of the second comparative example shown in FIG. 13, many fans 213 are required to cool multiple IGBT units 230 evenly.

On the other hand, according to the first to third embodiments shown in FIGS. 1 to 7 and FIGS. 9 to 11, even when multiple IGBT units 30 are arranged, the number of fans 13 used can be made smaller than in the second comparative example shown in FIG. 13. In addition, according to the first to third embodiments shown in FIGS. 1 to 7 and FIGS. 9 to 11, compared with the second comparative example, the amount of conductors used can be reduced and conductor connections can be simplified and optimized while improving environmental resistance, ensuring cooling performance, simplifying cooling flow paths, and improving replaceability.

### Third Comparative Example

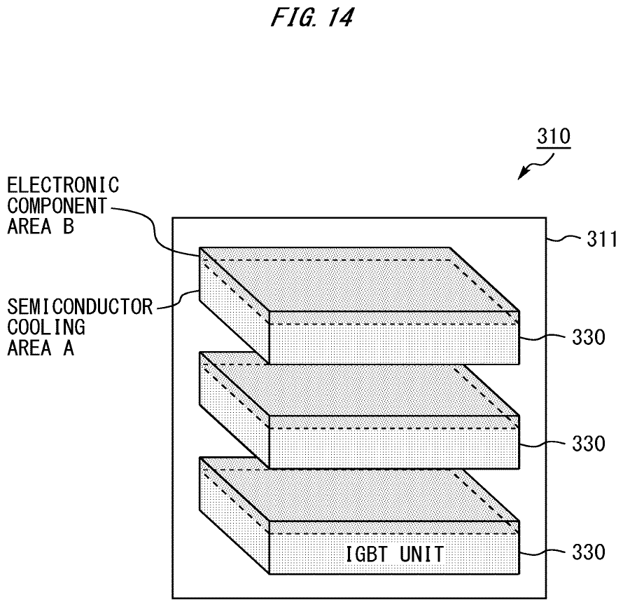

FIG. 14 shows an example of the layout structure of the IGBT unit 330 in the power conversion device 310 according to the third comparative example.

As shown in FIG. 14, like in the second comparative example shown in FIG. 13, the power conversion device 310 includes multiple IGBT units 330 arranged in multiple layers in a panel (housing) 311 like a server rack. In FIG. 14, the upper part of each IGBT unit 330 is an electronic component area B where, for example, semiconductor units 32 and gate driver boards 33 are arranged, and the lower part is a semiconductor cooling area A where, for example, a cooler 31 is arranged.

For example, in the structure of the third comparative example shown in FIG. 14, for area partitioning, a simpler structure with less pressure loss is more advantageous in terms of cooling, as the electronic component area B has little airflow because the contamination due to outside air is kept as low as possible compared to the semiconductor cooling area A. However, as in the third comparative example, when IGBT units 330 are stacked vertically in a single line, area partitioning (separating inside and outside air) complicates the structure of the electronic component area B which is mounted with precision machinery such as gate driver boards 33. In the first place, with a layout structure where IGBT units 330 are vertically stacked in multiple layers as in the third comparative example, it is difficult to separate the semiconductor cooling area A from the electronic component area B which is mounted with gate driver boards 33 and other components that should be protected from contamination from the outside air in the IGBT units 330.

On the other hand, according to the first to third embodiments shown in FIGS. 1 to 7 and 9 to 11, which employ a layout structure in which IGBT units 30 face each other, the structure of the electronic component area B is simpler than that of the third comparative example shown in FIG. 14, allowing for less pressure loss and more efficient cooling. According to the first to third embodiments shown in FIGS. 1 to 7 and FIGS. 9 to 11, compared with the third comparative example, the amount of conductors used can be reduced and conductor connections can be simplified and optimized while improving environmental resistance, ensuring cooling performance, simplifying cooling flow paths, and improving replaceability.

### Supplemental Information on Embodiments

The first to third embodiments shown in FIGS. 1 to 7 and FIGS. 9 to 11 are divided into the first embodiment shown in FIGS. 1 to 7 and 9, the second embodiment shown in FIG. 10, and the third embodiment shown in FIG. 11 although they may be combined in series or in parallel. A combination of embodiments can have the same effects as those produced by the individual embodiments before being combined.

The features and advantages of the embodiments should be clear from the detailed description above. This means that the claims cover the features and advantages of the aforementioned embodiments without departing from the spirit and scope of the claims. Further, those skilled in the art should be able to readily conceive all improvements and modifications. Therefore, the inventive embodiments are not to be taken as being limited to the description above and may depend on appropriate modifications and equivalents included in the scope disclosed in the embodiments.

### REFERENCE SIGNS LIST

1 Photovoltaic power generation system (power conversion system)
2 Photovoltaic panel
3 Transformer
4 Alternating current power grid (grid)
5 Direct current bus
5a Direct current input unit
6 Alternating current circuit
10, 10A, 10B Power conversion device (PCS)
11, 11A, 11B Housing (panel)
12 Air intake (first air intake)
13 Fan (cooling fan)
14 Air intake (second air intake)
14a Air filter
15 Heat exchanger
16 Bulkhead (metal plate)
21 direct current switch (direct current circuit breaker, DC switch)
22 Direct current capacitor (DC capacitor)
24 Alternating current filter (AC filter)
24a Alternating current reactor (AC reactor)
24b Alternating current capacitor (AC capacitor)
25 Alternating current switch (alternating current circuit breaker, AC switch)
30 Three-phase in one enclosure semiconductor unit (IGBT unit, first three-phase in one enclosure semiconductor unit, second three-phase in one enclosure semiconductor unit)
31 Cooler
32 Semiconductor unit (semiconductor device, IGBT)
33 Gate driver board
34 Main circuit conductor (laminated bus bar)
35 Support member
36 Direct current terminal
37 Alternating current terminal
37a Alternating current terminal (first alternating current terminal)
37b Alternating current terminal (second alternating current terminal)
37c Alternating current terminal (third alternating current terminal)
40 Control device
41 Control board
42 Main control board
43, 43′ Signal distribution board
110 Power conversion device (PCS)
111 Housing (panel)
113 Fan (Cooling fan)
130 three-phase in one enclosure semiconductor unit (IGBT unit)
210 Power conversion device (PCS)
211 Housing (panel)
213 Fan (cooling fan)
230 Three-phase in one enclosure semiconductor unit (IGBT unit)
310 Power conversion device (PCS)
311 Housing (panel)
330 Three-phase in one enclosure semiconductor unit (IGBT unit)
A Semiconductor cooling area
B Electronic component area

1. A power conversion device comprising:
a housing;
a first three-phase in one enclosure semiconductor unit; and
a second three-phase in one enclosure semiconductor unit, the first three-phase in one enclosure semiconductor unit and the second three-phase in one enclosure semiconductor unit being arranged in the housing and having the same structure, wherein
the first three-phase in one enclosure semiconductor unit and the second three-phase in one enclosure semiconductor unit each include:
a cooler, a semiconductor unit, a gate driver board, a first alternating current terminal, a second alternating current terminal, and a third alternating current terminal,
the cooler is arranged in an outer portion of the housing, and the first alternating current terminal, the second alternating current terminal, and the third alternating current terminal are arranged facing each other inside the housing so that the semiconductor unit, the gate driver board, the first alternating current terminal, the second alternating current terminal, and the third alternating current terminal are arranged in an inner portion of the housing,
the first three-phase in one enclosure semiconductor unit is configured so that a signal distribution board of the power conversion device transmits a U-phase signal to the first alternating current terminal, a V-phase signal to the second alternating current terminal, and a W-phase signal to the third alternating current terminal, and
the second three-phase in one enclosure semiconductor unit is configured so that the signal distribution board of the power conversion device replaces wiring so that the U-phase and W-phase are reversed, and transmits a W-phase signal to the first alternating current terminal, a V-phase signal to the second alternating current terminal, and a U-phase signal to the third alternating current terminal.

2. The power conversion device according to claim 1, wherein
the first alternating current terminal of the first three-phase in one enclosure semiconductor unit and the third alternating current terminal of the second three-phase in one enclosure semiconductor unit to both of which the U-phase signal is transmitted by the signal distribution board are connected facing each other in the inner portion of the housing,
the second alternating current terminal of the first three-phase in one enclosure semiconductor unit and the second alternating current terminal of the second three-phase in one enclosure semiconductor unit to both of which the V-phase signal is transmitted by the signal distribution board are connected facing each other in the inner portion of the housing, and
the third alternating current terminal of the first three-phase in one enclosure semiconductor unit and the first alternating current terminal of the second three-phase in one enclosure semiconductor unit to both of which the W-phase signal is transmitted by the signal distribution board are connected facing each other in the inner portion of the housing.

3. The power conversion device according to claim 1, wherein
the housing includes:
a first air intake that takes in outside air to cool a semiconductor cooling area arranged in the outer portion of the housing;
a second air intake that takes in clean air through an air filter to cool an electronic component area arranged in the inner portion of the housing; and
a cooling fan,
the semiconductor cooling area and the electronic component area are separated in the housing so that only outside air taken in through the first air intake flows into the semiconductor cooling area and only clean air taken in through the second air intake through the air filter flows into the electronic component area, and
the cooling fan is configured to exhaust the outside air and clean air that have merged after flowing separately inside the housing.

4. The power conversion device according to claim 1, wherein
the housing includes:
a first air intake that takes in outside air to cool a semiconductor cooling area arranged in the outer portion of the housing;
a heat exchanger that absorbs heat from the inside air that cools an electronic component area arranged in the inner portion of the housing; and
a cooling fan,
the semiconductor cooling area and the electronic component area are separated in the housing so that only the outside air taken in through the first air intake flows into the semiconductor cooling area and only the inside air that has been cooled by heat absorption by the heat exchanger flows and circulates in the electronic component area, and
the cooling fan is configured to exhaust only the outside air.

5. The power conversion device according to claim 2, wherein
multiple pairs each consisting of the first three-phase in one enclosure semiconductor unit and the second three-phase in one enclosure semiconductor unit are aligned in a vertical direction in the housing,
multiple pairs each consisting of the first alternating current terminals of the first three-phase in one enclosure semiconductor unit and the third alternating current terminals of the second three-phase in one enclosure semiconductor unit, which are connected facing each other in the inner portion of the housing, are also connected in the vertical direction,
multiple pairs each consisting of the second alternating current terminal of the first three-phase in one enclosure semiconductor unit and the second alternating current terminal of the second three-phase in one enclosure semiconductor unit, which are connected facing each other in the inner portion of the housing, are also connected in the vertical direction, and
multiple pairs each consisting of the third alternating current terminal of the first three-phase in one enclosure semiconductor unit and the first alternating current terminal of the second three-phase in one enclosure semiconductor unit, which are connected facing each other in the inner portion of the housing, are also connected in the vertical direction.
